(19) United States
(12) Patent Application Publication
(10) Pub. No.: US 2024/0250057 A1
(43) Pub. Date: Jul. 25, 2024

(54) SEMICONDUCTOR PACKAGE AND METHOD OF MANUFACTURING THE SAME

(71) Applicant: JMJ Korea Co., Ltd., Busan (KR)

(72) Inventor: Yun Hwa CHOI, Busan (KR)

(73) Assignee: JMJ Korea Co., Ltd., Busan (KR)

(21) Appl. No.: 18/384,389

(22) Filed: Oct. 27, 2023

(30) Foreign Application Priority Data
Jan. 19, 2023 (KR) 10-2023-0008018

(51) Int. Cl. H01L 23/00; H01L 23/14; H01L 23/31; H01L 23/367; H01L 23/498; H01L 25/065

(52) U.S. Cl. CPC H01L 24/40; H01L 23/14; H01L 23/3107; H01L 23/3672; H01L 23/49822; H01L 23/49838; H01L 24/41; H01L 25/0655; H01L 2224/4005; H01L 2224/40225; H01L 2224/41051; H01L 2924/10251; H01L 2924/1203; H01L 2924/13055; H01L 2924/13062; H01L 2924/13091; H01L 2924/181

(57) ABSTRACT

Provided is a semiconductor package and a method of manufacturing the same, and more particularly, to a semiconductor package and a method of manufacturing the same in which stress applied while molding is efficiently dispersed by a three-dimensional clip structure so that structural reliability may be improved.

### CROSS-REFERENCE TO RELATED PATENT APPLICATION

This application claims the benefit of Korean Patent Application No. 10-2023-0008018, filed on Jan. 19, 2023, in the Korean Intellectual Property Office, the disclosure of which is incorporated herein in its entirety by reference.

### BACKGROUND OF THE INVENTION

### 1. Field of the Invention

The present invention relates to a semiconductor package and a method of manufacturing the same, and more particularly, to a semiconductor package and a method of manufacturing the same in which stress applied while molding is efficiently dispersed by a three-dimensional clip structure so that structural reliability may be improved.

### 2. Description of the Related Art

In general, a semiconductor package includes semiconductor chips installed on a lower substrate or an upper substrate, conductors which are metal posts functioning as spacers bonded onto the semiconductor chips, lead frames formed of Cu to apply an electrical signal from the outside, and a package housing molded by a sealing member. Here, the semiconductor chips are bonded onto lead frame pads, and lead frame leads are electrically connected to the pads of the semiconductor chips through bonding wires, which are signal lines, by using a plating layer formed of Ag and interposed therebetween.

For example, as illustrated in a general semiconductor package of FIG. 1A, semiconductor chips 14 are bonded on a lower metal insulating substrate 11A by using first bonding units 12 interposed therebetween, hexahedral or cylindrical conductors 17, which are metal spacers each having a vertical structure, are bonded onto the semiconductor chips 14 by using second bonding units 16 interposed therebetween and are bonded onto a upper metal insulating substrate 11B by using third bonding units 13 interposed therebetween, and metal bridges having a vertical structure are formed between the lower metal insulating substrate 11A and the upper metal insulating substrate 11B for electrical connection.

Semiconductor chips are each bonded to substrates and conductors by using solders, however, cracks are generated in the first bonding unit 12 or the second bonding unit 16 as illustrated in FIG. 1B due to a Coefficient of Thermal Expansion (CTE) difference between the substrates 11A and 11B, the conductors 17, and the first and second bonding units 12 and 16. Accordingly, a reliability issue may be generated.

That is, a main cause of cracks in the bonding members due to a CTE difference is attributed to a direct shock to semiconductor chips applied by pressurizing an upper metal insulating substrate and metal spacers by a mold when the metal spacers bonded to the surfaces of the semiconductor chips are directly and vertically bonded to the upper metal insulating substrate and molding is executed to form a package housing. In this regard, the yield of products may be lowered.

Meanwhile, in order to minimize a CTE difference with semiconductor chips, metal spacers or metal posts may be replaced with a material similar to a CTE of the semiconductor chip, however, such material is considerably expensive compared with existing metal spacers or metal posts. Accordingly, price competitiveness of products is lowered.

### SUMMARY OF THE INVENTION

The present invention provides a semiconductor package and a method of manufacturing the same in which stress applied while molding is efficiently dispersed by a three-dimensional clip structure so that structural reliability may be improved.

According to an aspect of the present invention, there is provided a semiconductor package including: at least one first substrate and second substrate each including a specific metal pattern formed thereon to enable electrical connection; at least one semiconductor chip each bonded to one side surface of the first substrate, the second substrate, or the first and second substrates; at least one three-dimensional clip structure including one side surface bonded to one side surface of the at least one semiconductor chip and the other side surface bonded to each of the metal patterns of the first substrate, the second substrate, or the first and second substrates; at least one terminal lead each bonded to the first substrate, the second substrate, or the first and second substrates; and a package housing molded to cover the semiconductor chips, wherein one side surface of the three-dimensional clip structure bonded to the one side surface of the semiconductor chip is extended in an X-axis direction and the other side surface of the three-dimensional clip structure bonded to each of the metal patterns of the first substrate, the second substrate, or the first and second substrates is extended in a Y-axis direction which is perpendicular to the X-axis direction.

Here, one side surface of the three-dimensional clip structure may include a first surface which forms a first bonded contact point with the semiconductor chip, the other side surface of the three-dimensional clip structure may include a second surface which forms a second bonded contact point with the first substrate or the metal pattern of the second substrate and a third surface which forms two separate third bonded contact points with the second substrate or the metal pattern of the first substrate, and the first surface and the second surface may be bent to form a level difference.

Here, the other side surface of the three-dimensional clip structure may be extended from both sides of the second surface and may be bent to have a semi-circular arch form.

Also, the three-dimensional clip structure may include an upper surface and a lower surface facing the upper surface, and the first surface, the second surface, or the third surface may be formed on any one same surface from among the upper surface and the lower surface.

Also, the three-dimensional clip structure may have a stacked structure comprising at least two layers of each different metal.

Also, the terminal lead may have a stacked structure comprising at least two layers of each different metal.

Also, the first substrate or the second substrate may include at least one insulating layer.

Also, the first substrate or the second substrate may include a single metal layer or a mixed metal layer in an alloy form or a plated form.

Also, the first substrate or the second substrate may have a stacked structure including at least one lower metal layer, at least one upper metal layer, and at least one insulating layer interposed between the lower metal layer and the upper metal layer.

Also, the semiconductor chip may be a power semiconductor chip comprising an Insulated Gate Bipolar Transistor (IGBT), a Metal-Oxide-Semiconductor Field-Effect Transistor (MOSFET), or a diode.

Also, one side surface of the three-dimensional clip structure may have a lower structure joining the one side surface of the semiconductor chip and the other side surface of the three-dimensional clip structure may have an upper structure joining the first substrate or the metal pattern of the second substrate so that a three-dimensional structure may be formed.

Also, the terminal lead may be bonded to the first substrate, the second substrate, or the first and second substrates by using soldering, sintering, or ultrasonic welding.

Also, the other side of the first substrate or the second substrate may be partially or entirely exposed to one side surface or the other side surface of the package housing.

Here, radiation fins may be further included on the other side surface of the first substrate or the second substrate exposed from the package housing

Also, a metal layer containing 50% or more of Ni may be coated on an area of above 80% of the other side of the first substrate or the second substrate exposed from the package housing.

Also, the other side surface of the first substrate or the second substrate may include a heat sink bonded thereto by using a heat transfer material.

Here, the heat transfer material may be bonded to the other side surface of the first substrate or the second substrate by hardening solder containing Sn or paste containing Ag or Cu.

Also, the surface of one side surface of the semiconductor chip bonded to the three-dimensional clip structure may contain 50% or more of Ag or Au.

Also, the three-dimensional clip structure may be bonded to an area of above 30% of one side surface of the semiconductor chip and at least one electrical connecting member may be ultrasonic bonded to a remaining area of below 70% of one side surface of the semiconductor chip, that is not overlapped.

Also, the number of the three-dimensional clip structure may be at least two and the at least two three-dimensional clip structures may be individually and separately formed or formed as one body.

Also, the semiconductor package may be used in a power converting device that converts power through a power semiconductor.

Also, the first bonded contact point or the second bonded contact point may include a hole formed thereon.

Here, a bonding unit in a form of stairs including one or more steps may be further formed around the hole in the first bonded contact point.

Also, a gap distance between the other side surfaces which face each other at the upper parts of the semi-circular arches may be 10 μm through 10 mm.

According to another aspect of the present invention, there is provided a method of manufacturing a semiconductor package including: preparing at least one first substrate and second substrate including a specific metal pattern formed thereon to enable electrical connection; bonding the at least one semiconductor chip to one side surface of the first substrate, the second substrate, or the first and second substrates; bonding one side surface of at least one three-dimensional clip structure to one side surface of the at least one semiconductor chip and bonding the other side surface of the at least one three-dimensional clip structure to metal patterns of the first substrate, the second substrate, or the first and second substrates; bonding at least one terminal lead to the first substrate, the second substrate, or the first and second substrates; and molding a package housing to cover the semiconductor chips, wherein one side surface of the three-dimensional clip structure bonded to the one side surface of the semiconductor chip is extended in an X-axis direction and the other side surface of the three-dimensional clip structure bonded to each of the metal patterns of the first substrate, the second substrate, or the first and second substrates is extended in a Y-axis direction which is perpendicular to the X-axis direction.

Here, one side surface of the three-dimensional clip structure may include a first surface which forms a first bonded contact point with the semiconductor chip, the other side surface of the three-dimensional clip structure may include a second surface which forms a second bonded contact point with the first substrate or the metal pattern of the second substrate and a third surface which forms two separate third bonded contact points with the second substrate or the metal pattern of the first substrate, and the first surface and the second surface may be bent to form a level difference.

Here, the three-dimensional clip structure may be formed by a first step which prepares a flat plate clip structure in a crossing half-cross form and by a second step which forms the third bonded contact point of the flat plate clip structure after bending the both sides of the second surface in a semi-circular arch form.

Here, the method may further include bending the first surface and the second surface to form a level difference, after the first step.

Here, the method may further include perforating for the first bonded contact point and the second bonded contact point on the first surface or the second surface, after the first step.

### BRIEF DESCRIPTION OF THE DRAWINGS

The above and other features and advantages of the present invention will become more apparent by describing in detail exemplary embodiments thereof with reference to the attached drawings in which:

FIGS. 1A and 1B illustrate semiconductor packages according to a conventional art;

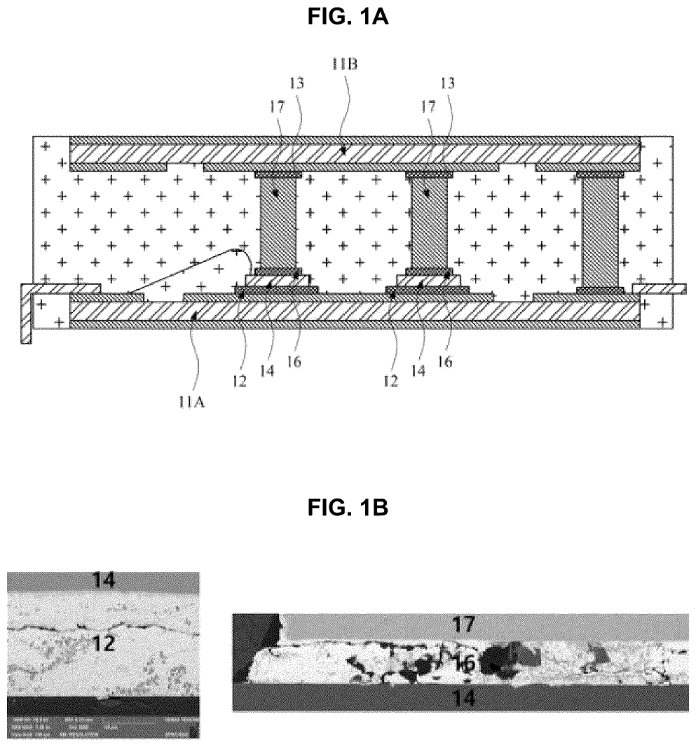

FIG. 2 is a cross-sectional view of a semiconductor package according to an embodiment of the present invention;

FIG. 3 separately illustrates an inner structure of the semiconductor package of FIG. 2;

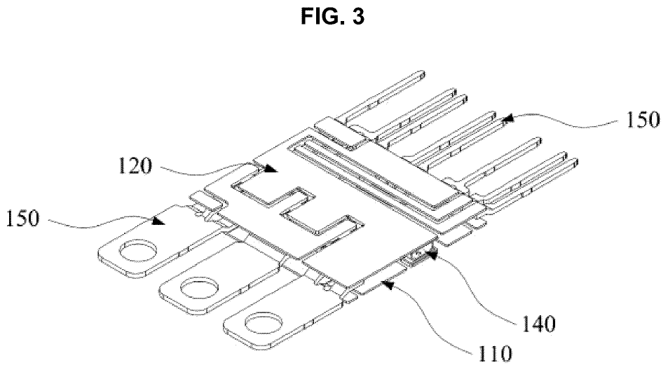

FIG. 4 is an exploded view of FIG. 3;

FIGS. 5A and 5B separately illustrate a three-dimensional clip structure of the semiconductor package of FIG. 2;

FIG. 6 illustrates a bonding structure of the three-dimensional clip structures of FIGS. 5A and 5B;

FIG. 7 illustrates the three-dimensional clip structures of FIGS. 5A and 5B according to another embodiment of the present invention;

FIGS. 8A and 8B respectively illustrate a heat radiation structure of the semiconductor package of FIG. 2; and

FIG. 9 is a flowchart illustrating a method of manufacturing a semiconductor package according to another embodiment of the present invention.

### DETAILED DESCRIPTION OF THE INVENTION

Hereinafter, embodiments of the present invention will be described in more detail with reference to the accompanying drawings.

A semiconductor package according to an embodiment of the present invention includes at least one first substrate 110 and second substrate 120, at least one semiconductor chip 130, at least one three-dimensional clip structure 140, at least one terminal lead 150, and a package housing 160, wherein the first and second substrates 110 and 120 include a specific metal pattern formed thereon to enable electrical connection, the at least one semiconductor chip 130 is each bonded to one side surface of the first substrate 110, the second substrate 120, or the first and second substrates 110 and 120, the at least one three-dimensional clip structure 140 includes one side surface bonded to one side surface of the at least one semiconductor chip 130 and the other side surface bonded to each of the metal patterns of the first substrate 110, the second substrate 120, or the first and second substrates 110 and 120, the at least one terminal lead 150 is each bonded to the first substrate 110, the second substrate 120, or the first and second substrates 110 and 120, and the package housing 160 is molded to cover the semiconductor chips 130. Here, one side surface of the three-dimensional clip structure 140 bonded to the one side surface of the semiconductor chip 130 is extended in an X-axis direction. The other side surface of the three-dimensional clip structure 140 bonded to each of the metal patterns of the first substrate 110, the second substrate 120, or the first and second substrates 110 and 120 is extended in a Y-axis direction which is perpendicular to the X-axis direction. Accordingly, stress applied while molding may be efficiently dispersed by the three-dimensional clip structure 140 and thereby, structural reliability may be improved.

Hereinafter, the semiconductor package mentioned above will be described in more detail with reference to the accompanying drawings.

First, one or more first substrates 110 and second substrates 120 are included, wherein the first substrate 110 and the second substrate 120 face each other and are spaced apart from each other by the three-dimensional clip structure 140. Here, a specific pattern for gates, phases, collector contacts, cathodes, and anodes are each formed on the first substrate 110 and the second substrate 120 to enable electrical connection and the semiconductor chips 130 are installed on the first substrate 110 and the second substrate 120.

Here, the first substrate 110 and the second substrate 120 may be a Direct Bonding Copper (DBC) substrate.

Also, although not illustrated, the first substrate 110 and/or the second substrate 120 may include one or more insulating layers, may include a single metal layer, may include a mixed metal layer in an alloy form or a plated form, or may include a stacked structure including at least one lower metal layer, at least one upper metal layer, and at least one insulating layer interposed between the lower metal layer and the upper metal layer.

For example, the insulating layer may be formed of a single material including Al₂O₃, AlN, Si₃N₄, or PI or a composite material containing at least any one of Al₂O₃, AlN, Si₃N₄, and PI.

Next, one or more semiconductor chips 130 are included and are each bonded to one surface of the first substrate 110, the second substrate 120, or the first and second substrates 110 and 120 by using a conductive adhesive interposed therebetween.

Meanwhile, the semiconductor chip 130 is a power semiconductor chip such as an Insulated Gate Bipolar Transistor (IGBT), a Metal-Oxide-Semiconductor Field-Effect Transistor (MOSFET), a diode, or a Junction Field Effect Transistor (JFET) and is used to drive a device such as an inverter, a converter, or an on board charger (OBC) that converts or controls power by using the semiconductor chip mentioned above.

In this regard, the semiconductor package according to an embodiment of the present invention may be used in a power converting device that converts power through a power semiconductor. For example, the semiconductor package may be applied to a high-powered power converting device used to switch and control a motor which converts power from DC to AC in electric vehicle and hybrid electric vehicle.

Also, one side surface of the semiconductor chip 130 bonded to the three-dimensional clip structure 140 contains 50% or more of Ag or Au so that excellent electrical conductivity may be maintained and thermal conductivity may be increased.

In addition, the three-dimensional clip structure 140 may be electrically connected to an area of above 30% of one side surface of the semiconductor chip 130 and one or more electrical connecting members (for example, conductive wires) (not illustrated) may be electrically connected to a remaining area of below 70% of one side surface of the semiconductor chip 130, that is not overlapped, by being ultrasonic bonded to the metal pattern.

Next, the three-dimensional clip structure 140 has a three-dimensional structure and disperses Coefficient of Thermal Expansion (CTE) stress applied from the first substrate 110 and/or the second substrate 120 while molding. One side surface of the three-dimensional clip structure 140 is electrically connected to one side of the at least one semiconductor chip 130 and the other side surface of the three-dimensional clip structure 140 is structurally bonded to the metal pattern of the first substrate 110 and/or the second substrate 120.

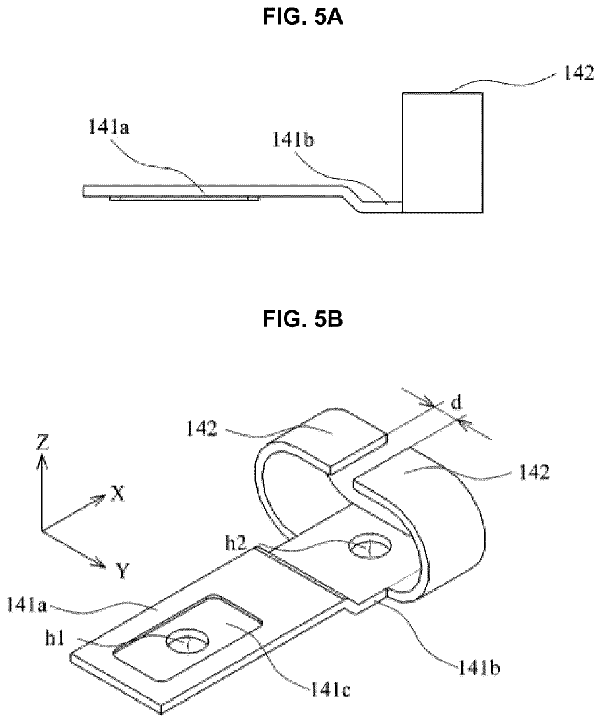

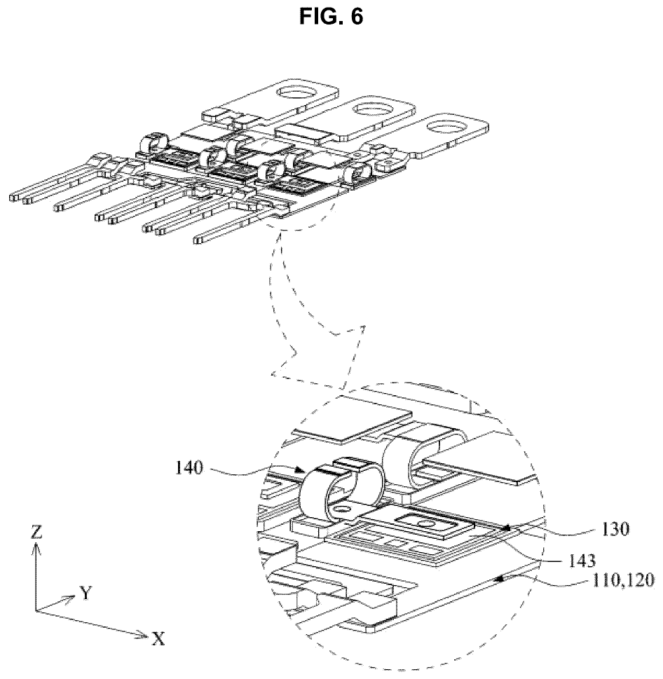

That is, referring to FIGS. 5A through 6, one side surface of the three-dimensional clip structure 140 bonded to one side surface of the semiconductor chip 130 is extended in an X-axis direction and the other side surface of the three-dimensional clip structure 140 each bonded to the first substrate 110, the second substrate 120, or the first and second substrates 110 and 120 is extended in a Y-axis direction. Accordingly, the three-dimensional clip structure 140 efficiently disperses CTE stress applied while the package housing 160 is molded and thereby, elastically absorbs push stress so as not to be directly delivered to the semiconductor chip 130. Also, generation of cracks in bonding units may be minimized and thus, structural reliability may be improved.

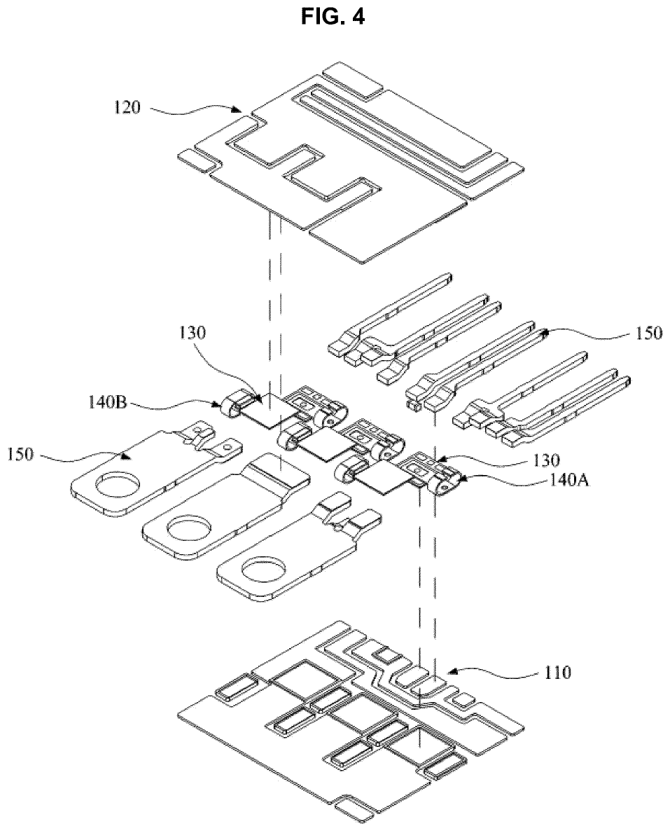

Meanwhile, as illustrated in FIG. 4, the three-dimensional clip structures 140 interposed between the first substrate 110 and the second substrate 120 may cross each other in an un-flipped state or a flipped state and may be combined with each other. For example, one side surface of an un-flipped three-dimensional clip structure 140A may be bonded to the first substrate 110 where the semiconductor chips 130 are installed and the other side surface thereof may be bonded to the second substrate 120 where the semiconductor chips 130 are not installed. One side surface of a flipped three-dimensional clip structure 140B may be bonded to the second substrate 120 where the semiconductor chips 130 are installed and the other side surface thereof may be bonded to the first substrate 110 where the semiconductor chips 130 are not installed.

As described above, the un-flipped and flipped three-dimensional clip structures 140A and 140B are bonded between the first substrate 110 and the second substrate 120 so that the CTE stress may not be weighted to any one substrate and instead, may be uniformly dispersed to left and right. Accordingly, structural reliability may be secured.

More specifically, as illustrated in FIGS. 5A through 6, one side surface of the three-dimensional clip structure 140 may include a first surface 141A and the other side of the three-dimensional clip structure 140 may include a second surface 141B and a third surface 142, wherein the first surface 141A forms a first bonded contact point with the semiconductor chip 130, the second surface 141B forms a second bonded contact point with the first substrate 110 or the metal pattern of the second substrate 120, and the third surface 142 forms a third bonded contact point with the facing second substrate 120 or the metal pattern of the first substrate 110. Here, the third bonded contact point may include two separate forms. Also, the first surface 141A and the second surface 141B may be bent and have a level difference in correspondence to a height difference between the first substrate 110 or the second substrate 120 and the semiconductor chip 130.

Here, referring to FIG. 5B, the first bonded contact point includes a hole h1 formed thereon so that an adhesive 143 (refer to FIG. 6) interposed between the semiconductor chip 130 and the first surface 141A included in one side surface of the three-dimensional clip structure 140 is partially overflowed through the hole h1 and is hardened. Accordingly, a path through which air bubble remaining in the adhesive 143 is moved out may be formed and adhesive strength may be increased.

As in the same manner, the second bonded contact point includes a hole h2 formed thereon so that an adhesive interposed between the first substrate 110 or the metal pattern of the second substrate 120 and the second surface 141B included in the other side surface of the three-dimensional clip structure 140 is partially overflowed through the hole h2 and is hardened. Accordingly, a path through which air bubble remaining in the adhesive is moved out may be formed and adhesive strength may be increased.

Also, a bonding unit 141C which has a level difference including one or more steps is further included around the hole h1 in the first bonded contact point so that adhesive strength with the overflowed adhesive 143 is increased through the hole h1 so as to efficiently respond to shear stress.

In addition, the third surface 142 included in the other side surface of the three-dimensional clip structure 140 includes two separate third bonded contact points. Accordingly, the number of bonded surfaces is increased to expand the bonded surfaces and to increase adhesive strength. Also, void (air bubble or micro gap) generated due to characteristics of an adhesive such as solder or sinter may be minimized compared with a single identical bonded surface. That is, as the bonded surface grows bigger, generatability of void increases. Here, while the same bonded surface is maintained, the bonded surface may be separated into two and an area of a separate bonded surface is reduced in half. Accordingly, generation of void may be suppressed.

Furthermore, as illustrated in FIG. 5B, the other side surface of the three-dimensional clip structure 140 is extended from both sides of the second surface 141B and is bent to have a semi-circular form so that two semi-circular arches which face each other are formed. In this regard, compared with one semi-circular arch, push stress may be efficiently balanced and dispersed left and right without being weighted to any one side. Here, a gap distance d between the other side surfaces which face each other at the upper parts of the semi-circular arches may be 10 μm through 10 mm.

More specifically, the three-dimensional clip structure 140 may include an upper surface and a lower surface facing the upper surface. Here, the first surface 141A, which forms the first bonded contact point with the semiconductor chip 130, and the second surface 141B, which forms the second bonded contact point with the metal pattern of the first substrate 110 or the second substrate 120, may be formed on the same surface, that is, any one same surface from among the upper surface and the lower surface. Also, the third surface 142, which forms the third bonded contact point with the metal pattern of the first substrate 110 or the second substrate 120 respectively facing the second substrate 120 and the first substrate 110 and forming the second bonded contact point described above may be formed on the same surface where the first surface 141A and the second surface 141B are formed, that is, any one same surface from among the upper surface and the lower surface. This is attributable to the third surface 142 extended from the both sides of the second surface 141B and bent to have a semi-circular arch form.

Also, the three-dimensional clip structure 140 has a stacked structure including at least two layers of each different metal such as Cu and Al and thus, has excellent ductility and malleability. Accordingly, push stress may be efficiently absorbed. In addition, the three-dimensional clip structure 140 may be formed of a single material including Cu or Al or a composite material containing 50% or more of Cu or Al.

In addition, one side surface of the three-dimensional clip structure 140 has a lower structure joining the one side surface of the semiconductor chip 130 and the other side surface of the three-dimensional clip structure 140 has an upper structure joining the first substrate 110 or the metal pattern of the second substrate 120 so that a three-dimensional structure may be formed. Here, according to the un-flipped or flipped state, the lower structure may be bonded to the semiconductor chip 130 installed on the first substrate 110 or the second substrate 120 and the upper structure may be bonded to the second substrate 120 or the first substrate 110 where the semiconductor chip 130 is not installed.

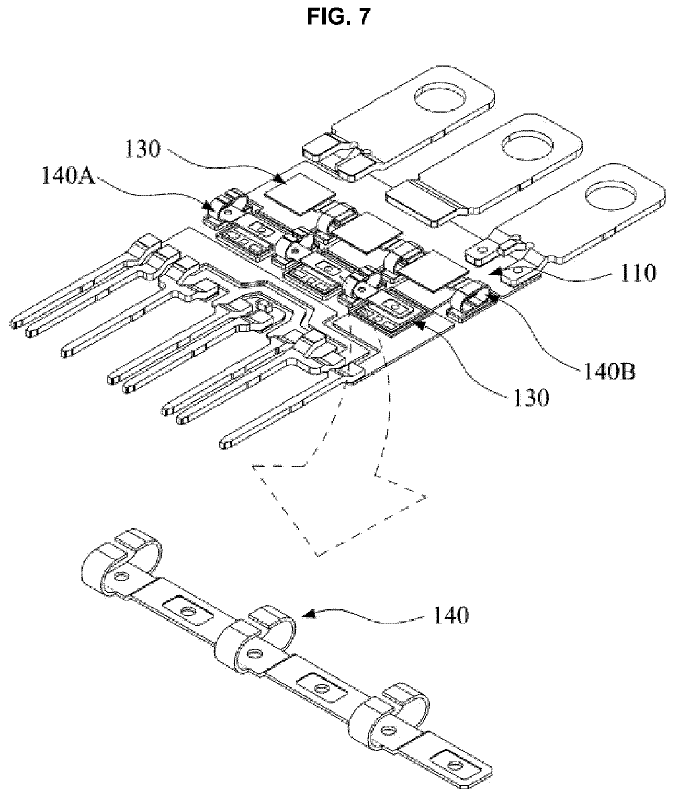

Meanwhile, in comparison with FIG. 4 and FIG. 7, at least two three-dimensional clip structures 140 may be individually and separately formed for each semiconductor chip 130 as illustrated in FIG. 4 or at least two three-dimensional clip structures 140 may be connected to each other and formed as one body as illustrated in FIG. 7.

Next, one or more terminal leads 150 may be included to structurally bonded to the first substrate 110, the second substrate 120, or the first and second substrates 110 and 120 so that an electrical signal may be applied.

Also, the terminal lead 150 may have a stacked structure including at least two layers of each different metal.

In addition, the terminal lead 150 may be bonded to the first substrate 110, the second substrate 120, or the first and second substrates 110 and 120 by using soldering, sintering, or ultrasonic welding.

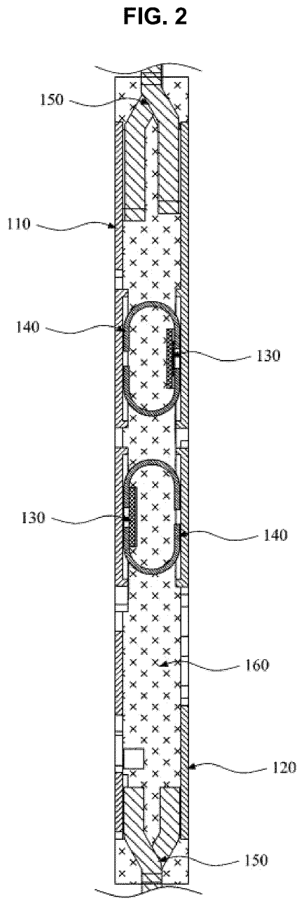

Next, referring to FIG. 2, the package housing 160 is formed of EMC, PBT, or PPS, is molded to cover the semiconductor chip 130 for insulation, and protects the semiconductor chip 130 and the three-dimensional clip structure 140.

In addition, the other side of the first substrate 110 or the second substrate 120 is partially or entirely exposed to one side surface or the other side surface of the package housing 160 so that heat generated while operating the semiconductor chip 130 may be transmitted to the outside of the package housing 160 and released.

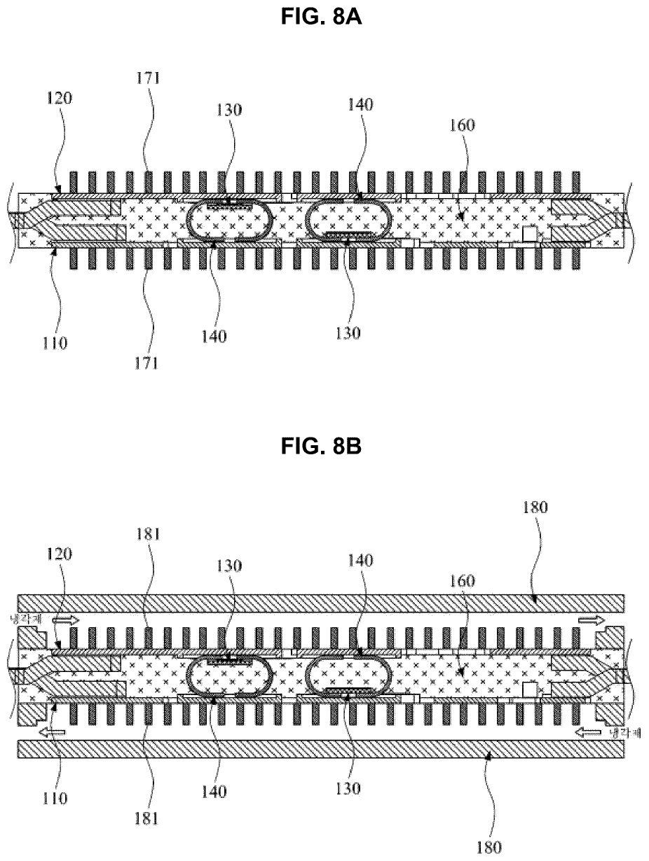

Moreover, referring to FIG. 8A, radiation fins 171 having excellent thermal conductivity are formed on the other side surface of the first substrate 110 or the second substrate 120 exposed from the package housing 160 and thereby, heat may be efficiently radiated through the radiation fins 171. Here, the radiation fins 171 may have a polygonal or circular cross section for excellent thermal conductivity.

Furthermore, a metal layer containing 50% or more of Ni may be coated on an area of above 80% of the other side of the first substrate 110 or the second substrate 120 exposed from the package housing 160 so that excellent strength, thermal resistance, and corrosion resistance may be maintained due to the nature of being exposed to the outside.

Also, referring to FIG. 8B, a heat sink 180, which radiates heat by using a heat transfer material 181 having excellent thermal conductivity, is bonded to the other side surface of the first substrate 110 or the second substrate 120 by using a Thermal Interface Material (TIM) interposed therebetween so that a coolant such as refrigerant, cooling oil, and cooling water may be circulated and cooling efficiency may be increased.

For example, any one from among cooling water, cooling liquid containing cooling water, cold air (air), and nitrogen may be selected as a coolant or a composite including any one from among cooling water, cooling liquid containing cooling water, cold air, and nitrogen may be used as a coolant.

Also, the heat transfer material 181 may be bonded to the other side surface of the first substrate 110 or the second substrate 120 by hardening solder containing Sn or paste containing Ag or Cu.

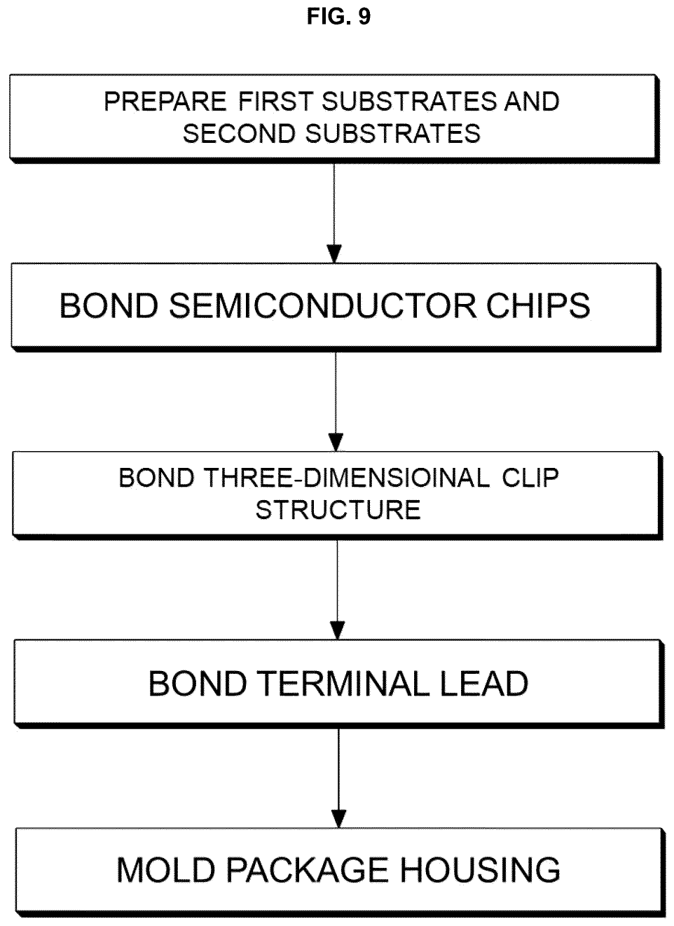

FIG. 9 is a flowchart illustrating a method of manufacturing a semiconductor package according to another embodiment of the present invention and is briefly described below.

More specifically, a method of manufacturing a semiconductor package includes preparing at least one first substrate 110 and second substrate 120 including a specific metal pattern formed thereon to enable electrical connection in operation S110, bonding the at least one semiconductor chip 130 to one side surface of the first substrate 110, the second substrate 120, or the first and second substrates 110 and 120 in operation S120, bonding one side surface of the at least one three-dimensional clip structure 140 to one side surface of the at least one semiconductor chip 130 and bonding the other side surface of the at least one three-dimensional clip structure 140 to the metal patterns of the first substrate 110, the second substrate 120, or the first and second substrates 110 and 120 in operation S130, bonding the at least one terminal lead 150 to the first substrate 110, the second substrate 120, or the first and second substrates 110 and 120 in operation S140, and molding the package housing 160 to cover the semiconductor chips 130 in operation S150.

Here, one side surface of the three-dimensional clip structure 140 bonded to one side surface of the semiconductor chip 130 is extended in an X-axis direction and the other side surface of the three-dimensional clip structure 140 bonded to each of the metal patterns of the first substrate 110, the second substrate 120, or the first and second substrates 110 and 120 is extended in a Y-axis direction which is perpendicular to the X-axis direction.

Also, one side surface of the three-dimensional clip structure 140 may include the first surface 141A and the other side of the three-dimensional clip structure 140 may include the second surface 141B and the third surface 142, wherein the first surface 141A forms the first bonded contact point with the semiconductor chip 130, the second surface 141B forms the second bonded contact point with the first substrate 110 or the metal pattern of the second substrate 120, and the third surface 142 forms the third bonded contact point with the facing second substrate 120 or the metal pattern of the first substrate 110. Here, the third bonded contact point may include two separate forms. In addition, the first surface 141A and the second surface 141B may be bent and have a level difference in correspondence to a height difference between the first substrate 110 or the second substrate 120 and the semiconductor chip 130.

Meanwhile, more specifically, the three-dimensional clip structure 140 may be formed by a first step which prepares a flat plate clip structure in a crossing half-cross (or ‘⊥’) form and by a second step which forms the other side surface of the flat plate clip structure after bending the both sides of the second surface 141B in a semi-circular arch form.

Here, a third step may be further included after the first step, wherein in the third step, the first surface 141A and the second surface 141B included in one side surface of the flat plate clip structure may be bent to form a level difference between the first surface 141A and the second surface 141B.

Also, a fourth step may be further included after the first step, wherein in the fourth step, perforating for the first bonded contact point and the second bonded contact point may be each performed on the first surface 141A or the second surface 141B.

Here, the order of the third step and the fourth step may include all cases which perform the fourth step after the third step and perform the third step after the fourth step.

Accordingly, as described above, a metal spacer may be replaced with the three-dimensional clip structure and thereby, the CTE stress applied while the package housing is molded may be efficiently dispersed. Also, three-dimensional clip structure may elastically absorb the push stress so as not be directly delivered to the semiconductor chips and generation of cracks in the bonding units may be minimized so that structural reliability may be improved. In addition, the bonded surfaces of the three-dimensional clip structure bonded to the substrates are physically separated to minimize poor quality of products occurring due to void and thus, adhesive strength may be increased.

Moreover, the push stress may be efficiently absorbed and dispersed by the three-dimensional clip structure where two semi-circular arches are symmetrically formed and may be balanced and dispersed left and right without being weighted to any one side.

According to the present invention, the CTE stress applied while the package housing is molded may be efficiently dispersed through the three-dimensional clip structure. Accordingly, the three-dimensional clip structure may elastically absorb the push stress so as not be directly delivered to the semiconductor chips and generation of cracks in the bonding units may be minimized so that structural reliability may be improved.

In addition, the bonded surfaces of the three-dimensional clip structure bonded to the substrates are physically separated to minimize poor quality of products occurring due to void and thus, adhesive strength may be increased.

Moreover, the push stress may be efficiently absorbed and dispersed by the three-dimensional clip structure where two semi-circular arches are symmetrically formed and may be balanced and dispersed left and right without being weighted to any one side.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
at least one first substrate and second substrate each comprising a specific metal pattern formed thereon to enable electrical connection;
at least one semiconductor chip each bonded to one side surface of the first substrate, the second substrate, or the first and second substrates;
at least one three-dimensional clip structure comprising one side surface bonded to one side surface of the at least one semiconductor chip and the other side surface bonded to each of the metal patterns of the first substrate, the second substrate, or the first and second substrates;
at least one terminal lead each bonded to the first substrate, the second substrate, or the first and second substrates; and
a package housing molded to cover the semiconductor chips,
wherein one side surface of the three-dimensional clip structure bonded to the one side surface of the semiconductor chip is extended in an X-axis direction and the other side surface of the three-dimensional clip structure bonded to each of the metal patterns of the first substrate, the second substrate, or the first and second substrates is extended in a Y-axis direction which is perpendicular to the X-axis direction.

2. The semiconductor package of claim 1, wherein one side surface of the three-dimensional clip structure comprises a first surface which forms a first bonded contact point with the semiconductor chip, the other side surface of the three-dimensional clip structure comprises a second surface which forms a second bonded contact point with the first substrate or the metal pattern of the second substrate and a third surface which forms two separate third bonded contact points with the second substrate or the metal pattern of the first substrate, and the first surface and the second surface are bent to form a level difference.

3. The semiconductor package of claim 2, wherein the other side surface of the three-dimensional clip structure is extended from both sides of the second surface and is bent to have a semi-circular arch form.

4. The semiconductor package of claim 2, wherein the three-dimensional clip structure comprises an upper surface and a lower surface facing the upper surface, and the first surface, the second surface, or the third surface is formed on any one same surface from among the upper surface and the lower surface.

5. The semiconductor package of claim 1, wherein the three-dimensional clip structure has a stacked structure comprising at least two layers of each different metal.

6. The semiconductor package of claim 1, wherein the terminal lead has a stacked structure comprising at least two layers of each different metal.

7. The semiconductor package of claim 1, wherein the first substrate or the second substrate comprises at least one insulating layer, or a single metal layer, or a mixed metal layer in an alloy form, or a plated form or a stacked structure comprising at least one lower metal layer, at least one upper metal layer, and at least one insulating layer interposed between the lower metal layer and the upper metal layer.

8. The semiconductor package of claim 2, wherein one side surface of the three-dimensional clip structure has a lower structure joining the one side surface of the semiconductor chip and the other side surface of the three-dimensional clip structure has an upper structure joining the first substrate or the metal pattern of the second substrate so that a three-dimensional structure is formed.

9. The semiconductor package of claim 1, wherein the terminal lead is bonded to the first substrate, the second substrate, or the first and second substrates by using soldering, sintering, or ultrasonic welding.

10. The semiconductor package of claim 1, wherein the other side of the first substrate or the second substrate is partially or entirely exposed to one side surface or the other side surface of the package housing.

11. The semiconductor package of claim 10, further comprising radiation fins on the other side surface of the first substrate or the second substrate exposed from the package housing.

12. The semiconductor package of claim 10, further comprising a metal layer containing 50% or more of Ni coated on an area of above 80% of the other side of the first substrate or the second substrate exposed from the package housing.

13. The semiconductor package of claim 1, wherein the other side surface of the first substrate or the second substrate comprises a heat sink bonded thereto by using a heat transfer material.

14. The semiconductor package of claim 13, wherein the heat transfer material is bonded to the other side surface of the first substrate or the second substrate by hardening solder containing Sn or paste containing Ag or Cu.

15. The semiconductor package of claim 1, wherein the surface of one side surface of the semiconductor chip bonded to the three-dimensional clip structure contains 50% or more of Ag or Au.

16. The semiconductor package of claim 1, wherein the three-dimensional clip structure is bonded to an area of above 30% of one side surface of the semiconductor chip and at least one electrical connecting member is ultrasonic bonded to a remaining area of below 70% of one side surface of the semiconductor chip, that is not overlapped.

17. The semiconductor package of claim 1, wherein the number of the three-dimensional clip structure is at least two and the at least two three-dimensional clip structures are individually and separately formed or formed as one body.

18. The semiconductor package of claim 2, wherein the first bonded contact point or the second bonded contact point comprises a hole formed thereon.

19. The semiconductor package of claim 18, further comprising a bonding unit in a form of stairs comprising one or more steps around the hole in the first bonded contact point.

20. A method of manufacturing a semiconductor package comprising:
preparing at least one first substrate and second substrate comprising a specific metal pattern formed thereon to enable electrical connection;
bonding the at least one semiconductor chip to one side surface of the first substrate, the second substrate, or the first and second substrates;
bonding one side surface of at least one three-dimensional clip structure to one side surface of the at least one semiconductor chip and bonding the other side surface of the at least one three-dimensional clip structure to metal patterns of the first substrate, the second substrate, or the first and second substrates;
bonding at least one terminal lead to the first substrate, the second substrate, or the first and second substrates; and
molding a package housing to cover the semiconductor chips,
wherein one side surface of the three-dimensional clip structure bonded to the one side surface of the semiconductor chip is extended in an X-axis direction and the other side surface of the three-dimensional clip structure bonded to each of the metal patterns of the first substrate, the second substrate, or the first and second substrates is extended in a Y-axis direction which is perpendicular to the X-axis direction.
